(19) United States
(12) Patent Application Publication
(10) Pub. No.: US 2012/0193633 A1
(43) Pub. Date: Aug. 2, 2012

(54) SEMICONDUCTOR DEVICE AND METHOD FOR MANUFACTURING SAME

(75) Inventors: Akihiko Kohno, Osaka-shi (JP); Toshio Mizuki, Osaka-shi (JP); Kohichi Tanaka, Osaka-shi (JP)

(73) Assignee: SHARP KABUSHIKI KAISHA, Osaka-shi (JP)

(21) Appl. No.: 13/499,846

(22) PCT Filed: Sep. 21, 2010
(86) PCT No.: PCT/JP2010/066282

§ 371 Date: Apr. 2, 2012

(30) Foreign Application Priority Data
Oct. 1, 2009 (JP) 2009-229477

(51) Int. Cl. H01L 29/38; H01L 21/205

(52) U.S. Cl. 257/66; 438/488; 257/E21.102; 257/E29.105

(57) ABSTRACT

A method for fabricating a semiconductor device according to the present invention includes the steps of: (a) providing a substrate (11a) in a chamber (26); (b) supplying a microwave into the chamber (26) through a dielectric plate (24), of which one surface that faces the chamber is made of alumina, thereby depositing a microcrystalline silicon film (14) with an aluminum concentration of 1.0×10¹⁶ atoms/cm³ or less on the substrate (11a) by high-density plasma CVD process; and (c) making a thin-film transistor that uses the microcrystalline silicon film as its active layer. As a result, a semiconductor device including a TFT that uses a microcrystalline silicon film with a mobility of more than 0.5 cm²/Vs as its active layer is obtained.

### REFERENCE TO RELATED APPLICATIONS

This application is the national stage under 35 USC 371 of International Application No. PCT/JP2010/066282, filed Sep. 21, 2010, which claims priority from Japanese Patent Application No. 2009-229477, filed Oct. 1, 2009, the entire contents of which are incorporated herein by reference.

### FIELD OF THE INVENTION

The present invention relates to a semiconductor device and a method for fabricating the device, and more particularly relates to a semiconductor device that includes a microcrystalline silicon film as its active layer and a method for fabricating such a device.

### BACKGROUND OF THE INVENTION

Liquid crystal display devices and organic EL display devices in which a thin-film transistor (which will be referred to herein as a “TFT”) is provided for each pixel are very popular now. A TFT is made by patterning a semiconductor layer that has been deposited on a substrate such as a glass substrate. And a substrate on which TFTs have been formed is also called an “active-matrix substrate”.

As the TFTs, a TFT that uses an amorphous silicon film as its active layer (which will be referred to herein as an “amorphous silicon TFT”) and a TFT that uses a polysilicon film as its active layer (which will be referred to herein as a “polysilicon TFT”) have been used extensively.

Since carriers will move at higher mobility in a polysilicon film than in an amorphous silicon film, a polysilicon TFT can make a larger amount of ON-state crystal flow through it, and therefore can operate faster, than an amorphous silicon TFT. For that reason, a display panel, of which not only pixel TFTs but also part or even all of the TFTs for a driver and other peripheral circuits are polysilicon TFTs, has been developed. A driver that has been formed on an insulating substrate (which is typically a glass substrate) as a component of a display panel is sometimes called a “monolithic driver”. Drivers include a gate driver and a source driver, only one of which is sometimes regarded as a monolithic driver. In this description, the “display panel” refers herein to a portion of a liquid crystal display device or organic EL display device that includes a display area, and does not include the backlight or bezel of a liquid crystal display device.

To fabricate a polysilicon TFT, a complicated manufacturing process, including not only a laser crystallization process step to crystallize an amorphous silicon film but also a thermal annealing process step and an ion doping process step, needs to be carried out, and therefore, the manufacturing cost per unit area of the substrate increases. For that reason, currently, polysilicon TFTs are used mainly in middle- and small-sized display devices, while amorphous silicon TFTs are used mostly in large-sized display devices.

Recently, however, in order to meet growing demands for not just display devices of even bigger sizes but also display devices that can achieve even higher image quality and even lower power dissipation, a TFT that uses a microcrystalline silicon (μc-Si) film as its active layer has been proposed as a TFT that realizes higher performance at a lower manufacturing cost than an amorphous silicon TFT (see Patent Documents Nos. 1 and 2 and Non-Patent Document No. 1, for example). Such a TFT will be referred to herein as a “microcrystalline silicon TFT”.

A microcrystalline silicon film is a silicon film that includes a crystalline phase and an amorphous phase and has a structure in which micro-crystal grains are dispersed in the amorphous phase. The size of the micro-crystal grains (on the order of several hundred nm or less) is smaller than that of crystal grains included in the polysilicon film. That is why those micro-crystal grains may sometimes be columnar crystals.

A microcrystalline silicon film may be formed by performing a plasma CVD process, for example. That is why a manufacturing facility for use to make an amorphous silicon film can be used as it is without performing any heat treatment for crystallization. In addition, since a microcrystalline silicon film achieves a higher carrier mobility (of more than 0.5 cm²/Vs) than an amorphous silicon film does, a TFT that has higher performance than an amorphous silicon TFT can be obtained. The microcrystalline silicon film may be formed by irradiating an amorphous silicon film that has been deposited on a substrate with a laser beam just like a polysilicon film. In addition, the amorphous silicon film should be irradiated with a laser beam for a shorter time than when a polysilicon film is formed, which is also beneficial.

In this description, the microcrystalline silicon film refers herein to a microcrystalline silicon film that has been formed by performing a plasma CVD process unless otherwise stated. As will be described later, a microcrystalline silicon film that has been formed through a plasma CVD process has a unique structure where crystals have grown on an incubation layer, which is a characteristic feature that makes it easy to distinguish such a microcrystalline silicon film from a microcrystalline silicon film that has been formed through a laser crystallization process.

For example, Patent Document No. 1 discloses that by using a microcrystalline silicon film as the active layer of a TFT, the amount of ON-state current to flow can be 1.5 times as large as that of an amorphous silicon TFT. On the other hand, Non-Patent Document No. 1 says that by using a semiconductor film of microcrystalline silicon and amorphous silicon, a TFT, of which the ON- to OFF-state current ratio is 10⁶, the mobility is about 1 cm²/Vs, and the threshold voltage is approximately 5 V, can be obtained. Furthermore, Patent Document No. 2 discloses a reverse staggered TFT that uses microcrystalline silicon.

### CITATION LIST

### Patent Literature

Patent Document No. 1: Japanese Patent Application Laid-Open Publication No. 6-196701
Patent Document No. 2: Japanese Patent Application Laid-Open Publication No. 5-304171
Patent Document No. 3: Japanese Patent Application Laid-Open Publication No. 2004-343039
Patent Document No. 4: Japanese Patent Application Laid-Open Publication No. 2006-244891
Patent Document No. 5: Japanese Patent Application Laid-Open Publication No. 2009-132948

### Non-Patent Literature

Non-Patent Document No. 1: Zhongyang Xu et al., “A Novel Thin-Film Transistors with μc-Si/a-Si Dual Active Layer Structure for AM-LCD”, IDW'96 Proceedings of the Third International Display Workshops, VOLUME 1, 1996, pp. 117 to 120

### SUMMARY OF INVENTION

However, when the present inventors actually made a TFT, of which the active layer was a microcrystalline silicon film that had been formed through a high-density plasma CVD process, and evaluated various characteristics of the TFT, the mobility of the microcrystalline silicon film was sometimes short of 0.5 cm²/Vs, which is the mobility of amorphous silicon.

It is therefore an object of the present invention to provide a semiconductor device including a TFT that uses a microcrystalline silicon film with a mobility of more than 0.5 cm²/V as its active layer, and also provide a method for fabricating such a semiconductor device.

A method for fabricating a semiconductor device according to the present invention includes the steps of: (a) providing a substrate in a chamber; (b) supplying a microwave into the chamber through a dielectric plate, of which one surface that faces the chamber is made of alumina, thereby depositing a microcrystalline silicon film with an aluminum concentration of 1.0×10¹⁶ atoms/cm³ or less on the substrate by high-density plasma CVD process; and (c) making a thin-film transistor that uses the microcrystalline silicon film as its active layer.

In one preferred embodiment, the step (b) is performed with that surface of the dielectric plate that faces the chamber partially covered with a metal layer.

A semiconductor device according to the present invention is characterized by being fabricated by a method according to any of the preferred embodiments of the present invention described above.

The present invention provides a semiconductor device including a TFT that uses a microcrystalline silicon film with a mobility of more than 0.5 cm²/V as its active layer, and also provides a method for fabricating such a semiconductor device.

### BRIEF DESCRIPTION OF DRAWINGS

FIG. 1 is a cross-sectional view schematically illustrating a TFT 10 of a semiconductor device as a preferred embodiment of the present invention.

FIG. 2 is a cross-sectional view schematically illustrating the configuration of a known high-density plasma CVD system 20.

FIG. 3 is a graph showing the gate voltage Vg to drain current Id characteristics of respective TFTs 10, of which the microcrystalline silicon films were deposited under Conditions a to c, respectively.

FIGS. 4(a) to 4(c) are graphs showing depth profiles that were obtained by SIMS (secondary ion mass spectroscopy) with respect to element aluminum in the microcrystalline silicon films that had been deposited under the Conditions a to c.

FIG. 5 is a cross-sectional view schematically illustrating the configuration of a high-density plasma CVD system 30 for use in the manufacturing process of a semiconductor device according to a preferred embodiment of the present invention.

FIG. 6 is a graph showing the gate voltage Vg to drain current Id characteristics of respective TFTs 10, of which the microcrystalline silicon films were deposited under Conditions d to f, respectively.

FIG. 7 is a graph summarizing how the mobility of a TFT changed with the concentration of element aluminum in the microcrystalline silicon film that had been formed under each of those conditions a through f.

### DETAILED DESCRIPTION OF THE INVENTION

Hereinafter, preferred embodiments of a semiconductor device and method for fabricating the device according to the present invention will be described with reference to the accompanying drawings. It should be noted, however, that the present invention is in no way limited to the specific preferred embodiments to be described below.

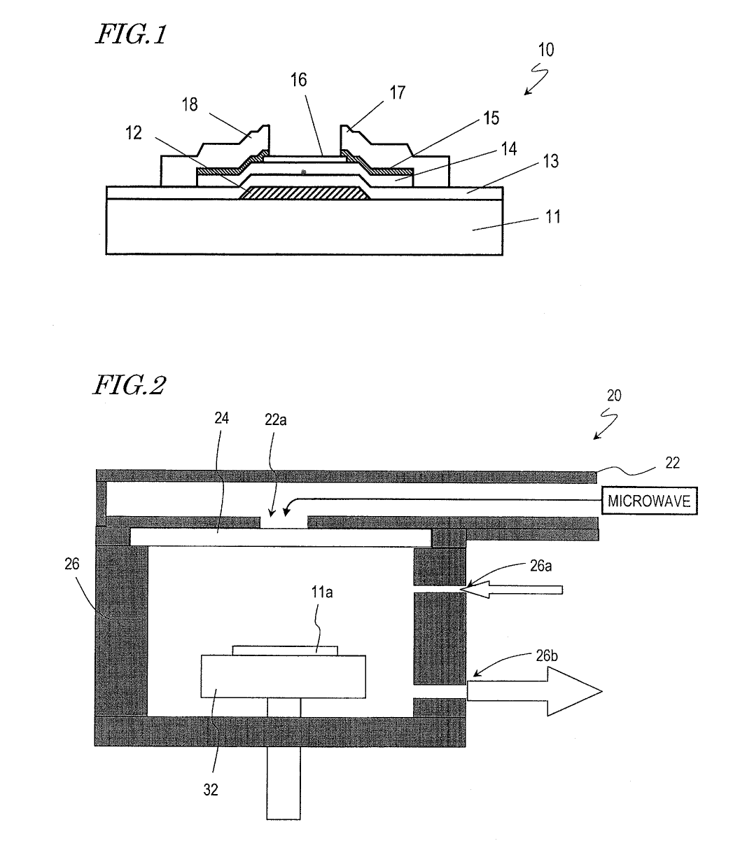

FIG. 1 is a cross-sectional view schematically illustrating a TFT 10 of a semiconductor device as a preferred embodiment of the present invention.

The TFT 10 includes a gate electrode 12 that has been formed on a substrate (such as a glass substrate) 11, a gate insulating film 13 that has been deposited over the gate electrode 12, and an active layer 14 that is arranged on the gate insulating film 13. The active layer 14 is a semiconductor layer and includes a microcrystalline silicon film in this example. The active layer 14 has a channel region, a source region and a drain region. An etch stop layer (functioning as a channel protective layer) 16 has been formed on the channel region of the active layer 14, while a contact layer (N⁺ silicon layer) 15 has been formed on the source/drain regions of the active layer 14. And a drain electrode 17 and a source electrode 18 have been formed on the contact layer 15.

This TFT 10 has the known structure except that the microcrystalline silicon film included in the active layer 14 is formed by the process to be described later and can be fabricated by the known process except the process step of forming the microcrystalline silicon film. In the following description, the active layer 14 is supposed to consist of the microcrystalline silicon film alone, and therefore, the microcrystalline silicon film and the active layer will be both identified herein by the same reference numeral 14. Optionally, the active layer may be a stack of the microcrystalline silicon film and an amorphous silicon film (see Japanese Patent Applications Laid-Open Publications Nos. 2005-322845 and 2008-140984, for example).

First of all, it will be described exactly how the present inventors made a sample of the TFT 10.

A Ti film was deposited to a thickness of 100 nm on a glass substrate 11 of 5 inch square and then patterned, thereby forming gate electrodes 12 there. Next, an SiNₓ film was deposited to a thickness of 410 nm as a gate insulating film 13.

After that, a microcrystalline silicon film 14 was deposited to a thickness of 50 nm by high-density plasma CVD process and then patterned into islands of microcrystalline silicon, thereby obtaining the active layer 14. This process step of forming the microcrystalline silicon film 14 will be described in detail later.

Now, it will be described exactly what the microcrystalline silicon film is.

The microcrystalline silicon film has a structure in which both crystalline silicon phases (i.e., crystal grains) and an amorphous silicon phase are included in the same mixture. The volume percentage of the amorphous phase to the entire microcrystalline silicon film may be controlled within the range of 5% to 95%. But the amorphous phase preferably has a volume percentage of 5% to 40%. In that case, the ON-OFF ratio of the TFT can be increased even more effectively. Also, if the microcrystalline silicon film is subjected to a Raman spectrum analysis using visible radiation, it can be seen that its spectrum has the highest peak at a wavelength of 520 cm⁻¹, which is a peak representing crystalline silicon, and also has a broad peak at a wavelength of 480 cm⁻¹, which is a peak representing amorphous silicon. The peak at a wavelength of around 480 cm⁻¹ representing amorphous silicon may at least be one-thirtieth as high as, and could at most be as high as, the peak around a wavelength of 520 cm⁻¹.

If a polysilicon film is subjected to a Raman spectrum analysis for the purpose of comparison, almost no amorphous components will be detected and the peak representing amorphous silicon will have a height of approximately zero. It should be noted that when a polysilicon film is grown, an amorphous phase could be left just locally depending on the crystallization condition. Even so, the volume percentage of that amorphous phase to the entire polysilicon film would be less than roughly 5% and the peak representing amorphous silicon would be less than approximately one-thirtieth as high as the peak representing polysilicon according to the Raman spectrum analysis.

A microcrystalline silicon film includes crystal grains and an amorphous phase. Also, a thin amorphous layer (which will be referred to herein as an “incubation layer”) could be formed on one side of the microcrystalline silicon film that is closer to the substrate. The incubation layer may have a thickness of several nanometers, for example, although it depends on the deposition condition of the microcrystalline silicon film. Nevertheless, according to the condition or method of depositing the microcrystalline silicon film (e.g., particularly when a high-density plasma CVD process is adopted), almost no incubation layer could be formed in some cases.

In general, crystal grains included in a microcrystalline silicon film are smaller than crystal grains that form a polysilicon film. If a cross section of a microcrystalline silicon film is observed through a transmission electron microscope (TEM), the crystal grains will have an average grain size of approximately 2 to 300 nm. In some cases, the crystal grains could be columnar ones that rise upward from the incubation layer to reach the top of the microcrystalline silicon film. If the crystal grains have a diameter of approximately 10 nm and if the volume percentage of crystal grains to the entire microcrystalline silicon film falls within the range of 60% to 85%, a microcrystalline silicon film of quality with few defects in the film can be obtained. According to results of experimental examples (including specific examples of the present invention and comparative examples) to be described later, the crystal grains included in the microcrystalline silicon film had grain sizes of 2 nm to 100 nm.

Next, an SiNₓ film was deposited to a thickness of 150 nm and then patterned, thereby forming an etch stop layer 16. Subsequently, an amorphous N⁺ silicon film was deposited to a thickness of 50 nm and then patterned to form a contact layer 15. Thereafter, a Ti film was deposited to a thickness of 100 nm and then patterned into the shapes of source and drain electrodes 18 and 17. Next, an SiNₓ film was deposited to a thickness of 265 nm and then patterned to form a passivation film (not shown). Finally, such a structure supported on the substrate 11 was thermally treated at 200° C. for one hour within a nitrogen atmosphere, thereby completing a microcrystalline silicon TFT 10.

The size of the TFT 10 was set to satisfy channel length L/channel width W=12 μm/20 μm. The mobility of the active layer 14 of the TFT 10 was measured in a saturated region where the source-drain voltage (Vds voltage) was 10 V.

Next, it will be described how to form the microcrystalline silicon film 14.

The microcrystalline silicon film 14 is formed by high-density plasma CVD process. As the high-density plasma CVD process, a surface wave plasma method (which is also called a “microwave plasma method”), an ICP (inductively coupled plasma) method, or an ECR (electron cyclotron resonance) method is preferably adopted. In this example, a high-density plasma CVD system 20 of the surface wave plasma type such as the one shown in FIG. 2 was used. FIG. 2 is a schematic cross-sectional view of the high-density plasma CVD system 20 of the surface wave plasma type. Alternatively, the high-density plasma CVD system 20 may be replaced with the system disclosed in one of Patent Documents Nos. 4 and 5, the entire disclosure of which is hereby incorporated by reference.

The high-density plasma CVD system 20 shown in FIG. 2 includes a waveguide 22 and a chamber 26. The waveguide 22 is made of a conductor (such as aluminum) and guides a microwave that has been generated by a microwave generator (not shown) to the chamber 26, which may be made of aluminum, for example. The microwave is radiated through a microwave radiation hole 22a of the waveguide 22 into the chamber 26. In some cases, multiple holes 22a may be cut through the waveguide 22. A portion of the waveguide 22 that is located at the ceiling of the chamber 26 functions as a sort of planar antenna. The microwave that has been radiated through the microwave radiation hole 22a is transmitted through a dielectric plate 24 and enters the chamber 26, which has a source gas inlet port 26a and an outlet port 26b. In the chamber 26, arranged is a heatable stage 32. A substrate 11a on which a TFT is going to be fabricated is mounted on the upper surface of the stage 32.

In this example, the dielectric plate 24 is preferably an alumina plate. Alternatively, a stack of a dielectric substrate made of a non-alumina dielectric material (such as a quartz plate) and an alumina film that has been deposited on the dielectric substrate to face the chamber may also be used as the dielectric plate 24. If such a dielectric plate 24, of which the surface that faces the chamber 26 is made of alumina, is used, then the amount of oxygen released can be reduced by approximately one digit, which is beneficial. In addition, since a system that is designed to deposit a microcrystalline silicon film on a glass substrate (motherboard) with a large area is a bulky one, the dielectric plate 24 is preferably an alumina plate in order to cut down the cost.

Typically, the dielectric plate 24 functions as a microwave transmitting plate. However, if a slow wave plate (not shown) is arranged on one side of the microwave transmitting plate to face the chamber 26 (see Patent Document No. 4, for example) in order to shorten the wavelength of the microwave released into the chamber 26, then the dielectric plate 24 functions as not only a microwave transmitting plate but also a slow wave plate as well. The slow wave plate is preferably made of the same material as the microwave transmitting plate and is made of alumina in this example. A plasma CVD system is designed so that an equivalent circuit formed by the planar antenna (which is a part of the waveguide), the microwave transmitting plate and the plasma satisfies a resonance condition. The same can be said even if a protective layer is arranged on one side of the microwave transmitting plate to face the chamber 26 (see Patent Document No. 5), for example.

Using a CVD system 20 including an alumina plate as the dielectric plate 24, a TFT 10 including a microcrystalline silicon film as its active layer 14 such as the one described above was fabricated. Specifically, the TFT 10 was fabricated under the following three Conditions a, b and c in order to examine what influence would be produced by the element aluminum included as an impurity in the microcrystalline silicon film.

Condition a: first of all, the residual deposited on the inner wall of the chamber 26 was removed using an original solvent, for example.

After that, a microcrystalline silicon film was deposited to a thickness of 50 nm ten times on every substrate but the sample. Each time the microcrystalline silicon film was deposited under the conditions including a microwave of 915 MHz, a power of 3.2 W/cm² (a power of 4.0 kW applied), a pressure of 20 mT, an SiH₄ flow rate of 6 sccm, an Ar flow rate of 126 sccm, a gap of 150 mm and a substrate temperature setting of 250° C.

Thereafter, without cleaning the inner wall of chamber 26, a microcrystalline silicon film to be the active layer 14 of the TFT 10 was deposited to a thickness of 50 nm. The film was deposited under the condition including a microwave of 915 MHz, a power of 3.2 W/cm² (a power of 4.0 kW applied), a pressure of 20 mT, an SiH₄ flow rate of 6 sccm, an Ar flow rate of 126 sccm, a gap of 150 mm and a substrate temperature setting of 250° C.

Condition b: first of all, the residual deposited on the inner wall of the chamber 26 was removed using an original solvent, for example.

After that, as in Condition a, a microcrystalline silicon film was deposited to a thickness of 50 nm ten times on every substrate but the sample. Each time the microcrystalline silicon film was deposited under the conditions including a microwave of 915 MHz, a power of 3.2 W/cm² (a power of 4.0 kW applied), a pressure of 20 mT, an SiH₄ flow rate of 6 sccm, an Ar flow rate of 126 sccm, a gap of 150 mm and a substrate temperature setting of 250° C.

Thereafter, without cleaning the inner wall of chamber 26, a microcrystalline silicon film to be the active layer 14 of the TFT 10 was deposited to a thickness of 50 nm as in Condition a. The film was deposited under a less strict condition than Condition a. Specifically, the film deposition condition included a microwave of 915 MHz, a power of 2.4 W/cm² (a power of 3.0 kW applied), a pressure of 20 mT, an SiH₄ flow rate of 6 sccm, an Ar flow rate of 126 sccm, a gap of 150 mm and a substrate temperature setting of 250° C.

Condition c: first of all, the residual deposited on the inner wall of the chamber 26 was removed using an original solvent, for example.

After that, unlike Conditions a and b, a microcrystalline silicon film to be the active layer 14 of the TFT 10 was deposited immediately to a thickness of 50 nm. The film deposition condition was the same as Condition a and included a microwave of 915 MHz, a power of 3.2 W/cm² (a power of 4.0 kW applied), a pressure of 20 mT, an SiH₄ flow rate of 6 sccm, an Ar flow rate of 126 sccm, a gap of 150 mm and a substrate temperature setting of 250° C.

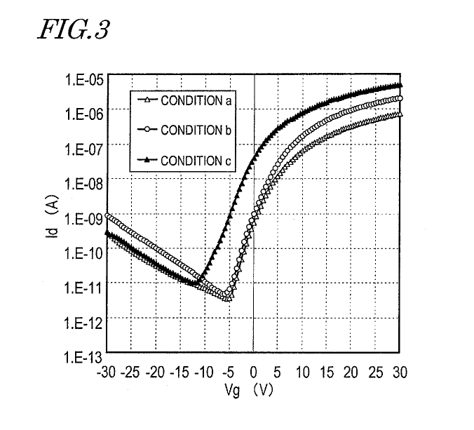

The present inventors measured the concentrations of aluminum at a point in the microcrystalline silicon films that had been deposited under these Conditions a to c (specifically, approximately 25 nm over the gate insulating film 13) by secondary ion mass spectroscopy (SIMS). We also measured the mobility values (at Vd==100 V) of the respective microcrystalline silicon films (i.e., the active layers) 14 of the TFTs 10. The results are summarized in the following Table 1. The gate voltage Vg to drain current Id characteristics of the respective TFTs 10 are shown in FIG. 3.

TABLE 1

| | Aluminum | |
|---|---|---|
| | concentration | Mobility |
| | [atoms/cm³] | [cm²/Vs] |
| Condition a | 4.0 × E17 | 0.10 |
| Condition b | 3.0 × E16 | 0.25 |
| Condition c | 5.0 × E15 | 0.60 |

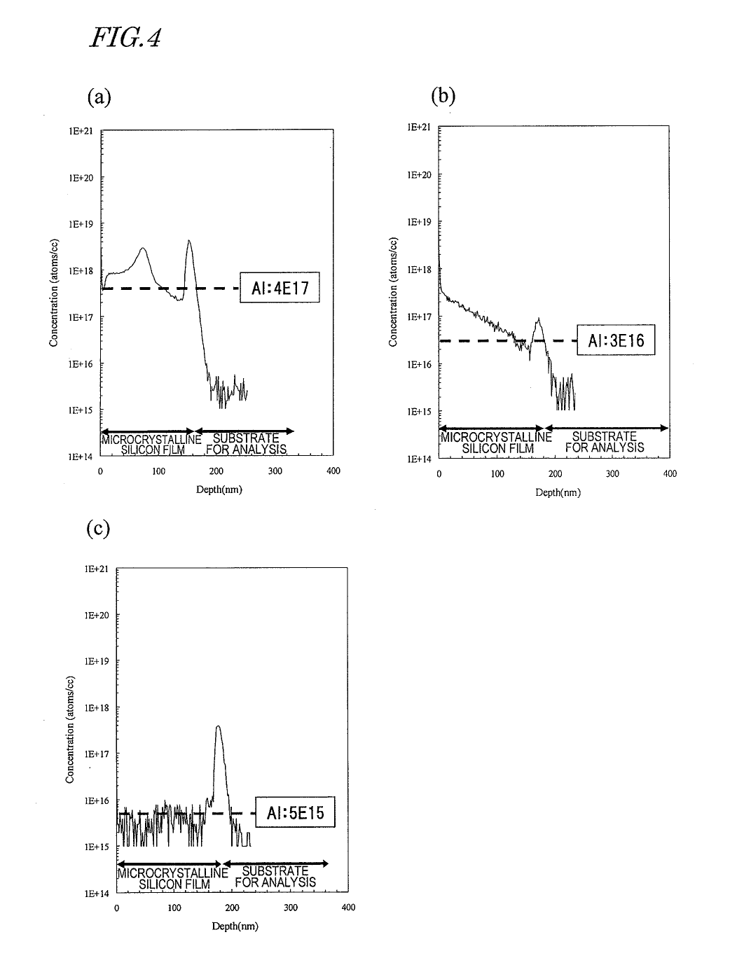

The present inventors also obtained, by SIMS (secondary ion mass spectroscopy), the depth profiles of the concentration of element aluminum in the microcrystalline silicon films that had been deposited under Conditions a to c. The results are shown in FIGS. 4(a) to 4(c). It should be noted that the SIMS depth profiles shown in FIGS. 4(a) to 4(c) were obtained with microcrystalline silicon films deposited to a thickness of approximately 150 to 180 nm on a substrate for analysis.

The results shown in Table 1 reveal that the higher the concentration of element aluminum in the microcrystalline silicon film 14, the lower the mobility. Specifically, the mobility values of the microcrystalline silicon films that were deposited under the Conditions a and b, including an element aluminum concentration of more than 1.0×E16 (=1.0×10¹⁶) atoms/cm³, is smaller than 0.5 cm²/Vs, which is a typical mobility of an amorphous silicon film. Thus it can be seen that in order to obtain a microcrystalline silicon film with a mobility of more than 0.5 cm²/Vs, the concentration of the element aluminum should be reduced to 1.0×E16 atoms/cm³ or less. Also, as can be seen from FIG. 3, a TFT, including a microcrystalline silicon film with an element aluminum concentration of 1.0×E16 atoms/cm³ or less (which was fabricated under the Condition c), has a good Vg-Id characteristic, and an ON-state current, which is greater than that of an amorphous silicon TFT, can be obtained.

As can be seen from the depth profiles of the element aluminum in the microcrystalline silicon films shown in FIGS. 4(a) through 4(c), the distribution of the element aluminum in the thickness direction does not have a uniform pattern but varies from one sample to another. However, since the element aluminum concentration clearly varies depending on the Condition a, b or c, it can be seen that the aluminum concentration shown in Table 1 is an appropriate value. Furthermore, as can be seen from FIG. 4(c), an element aluminum concentration of 1.0×E16 atoms/cm³ or less is close to the limit of the SIMS analysis.

Meanwhile, Patent Document No. 3 discloses a TFT, which uses a non-single crystal semiconductor film as its active layer and which is characterized by having oxygen and carbon concentrations of not more than 5×10¹⁷ atoms/cm³ in the non-single crystal semiconductor film and having a metallic element concentration of not more than 5×10¹⁶ atoms/cm³. The non-single crystal semiconductor film specifically disclosed in Patent Document No. 3 is a polysilicon film, not a microcrystalline silicon film. However, as already described with respect to the TFT that was fabricated on the Condition b, even if the element aluminum concentration in the microcrystalline silicon film were set to be 5×10¹⁶ atoms/cm³ or less as taught in Patent Document No. 3, a sufficiently high mobility would not be achieved.

The present inventors confirmed, based on the results of the SIMS, that each of the microcrystalline silicon films that had been deposited under the Conditions a to c had an oxygen concentration of approximately 1.0×E19 atoms/cm³. On the other hand, carbon was hardly detected because its concentration was below the detection limit of SIMS (that is 1.0×E19 atoms/cm³). It is known that if the concentration of oxygen in a microcrystalline silicon film is approximately 2.0×E19 atoms/cm³ or less, a high crystallization rate and a high mobility can be achieved at the same time (see J. Appl. Phys., Vol. 96, No. 4, 15 Aug. 2004, “Oxygen Impurity Doping into Ultrapure Hydrogenated Microcrystalline Si Films”).

In order to prevent the microcrystalline silicon film from including element aluminum while using a dielectric plate 24, of which the surface is made of alumina, a high-density plasma CVD system 30 such as the one shown in FIG. 5 was tentatively fabricated.

Unlike the high-density plasma CVD system 20 shown in FIG. 2, the high-density plasma CVD system 30 shown in FIG. 5 includes a metal plate 25, which partially covers the aluminum surface of the dielectric plate 24, on the dielectric plate 24 so as to face the chamber 26. In FIG. 5, any component also included in the high-density plasma CVD system 20 and having substantially the same function as its counterpart is identified by the same reference numeral and description thereof will be omitted herein. In this high-density plasma CVD system 30, the equivalent circuit, formed by the planar antenna (that is a part of the waveguide), the dielectric plate 24 (that is a microwave transmitting plate or a slow wave plate), the metal plate 25 and plasma, is designed so as to satisfy the resonance condition. Optionally, the high-density plasma CVD system 30 may be replaced with a modified one of the high-density plasma CVD system disclosed in Patent Document No. 4 or 5 with a metal plate mounted on the surface of the dielectric plate so as to face the chamber.

The shape, size and arrangement of the metal plate 25 were adjusted so as to generate plasma as uniformly as possible, and it was confirmed with the eyes that the plasma generated was sufficiently uniform. For example, it is preferred that the metal plate 25 be arranged at the center of the surface of the dielectric plate 24 so as to face the chamber 26, have a shape that is symmetric with respect to the center (e.g., a square, rectangular or diamond shape), and cover approximately 40-90% of that surface of the dielectric plate 24 that faces the chamber 26. Meanwhile, the plasma was measured with a Langmuir probe under the condition including a gas flow rate of Ar=200 sccm, a microwave power of 1.0 W/cm², and a pressure of 50 mT (=6.67 Pa) to 300 mT (=40.0 Pa) and with a point of measurement set within the range of 1 mm to 150 mm as measured from the surface of the metal plate 25. As a result, the electron density was within the range of 0.5×E12 cm³ to 5.0×E12 cm³ and the electron temperature was within the range of 1 eV to 3 eV These results are similar to the ones obtained by measuring the plasma with the plasma CVD system 20 described above. Thus, the electron density and electron temperature values are respectively high enough and low enough to deposit a microcrystalline silicon film of quality.

Using such a high-density plasma CVD system 30 including the metal plate 25, a TFT 10 including a microcrystalline silicon film as its active layer 14 as described above was fabricated. Specifically, the TFT 10 was fabricated under the following three Conditions d, e and f in order to examine what influence would be produced by the element aluminum included as an impurity in the microcrystalline silicon film.

According to each of these Conditions d, e and f, a microcrystalline silicon film was deposited without removing the residual from the inner wall of chamber 26. In each of these cases, the film was deposited under the same condition including a microwave of 915 MHz, a pressure of 20 mT (=2.67 Pa), an SiH₄ flow rate of 6 sccm, an Ar flow rate of 126 sccm, a gap of 150 mm and a substrate temperature setting of 250° C. but with only the microwave power changed as follows:
Condition d: a power of 3.2 W/cm² (a power of 4.0 kW applied),
Condition e: a power of 3.6 W/cm² (a power of 4.5 kW applied), and
Condition f: a power of 4.0 W/cm² (a power of 5.0 kW applied).

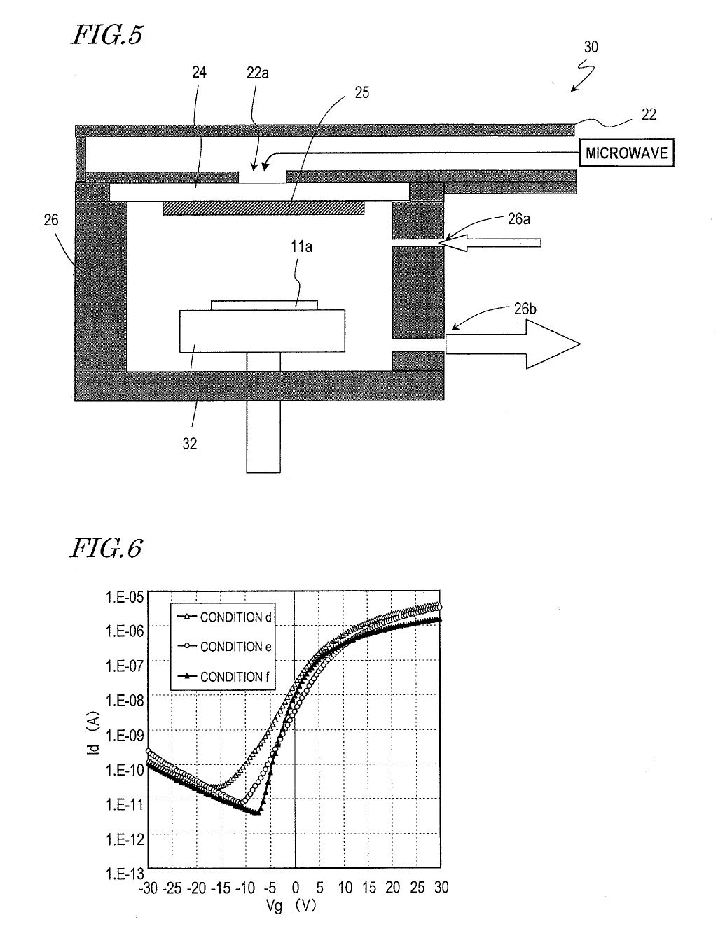

The present inventors measured the concentrations of aluminum at a point in the microcrystalline silicon films that had been deposited under these Conditions d to f (specifically, approximately 25 nm over the gate insulating film 13) by SIMS. We also measured the mobility values (at Vd=10 V) of the respective microcrystalline silicon films (i.e., the active layers) 14 of the TFTs 10. The results are summarized in the following Table 2. The gate voltage Vg to drain current Id characteristics of the respective TFTs 10 are shown in FIG. 6.

TABLE 2

| | Aluminum | |
|---|---|---|
| | concentration | Mobility |
| | [atoms/cm³] | [cm²/Vs] |
| Condition d | 6.0 × E15 | 0.65 |
| Condition e | 2.5 × E16 | 0.30 |
| Condition f | 3.0 × E17 | 0.20 |

The results shown in Table 2 reveal that the higher the concentration of element aluminum in the microcrystalline silicon film 14, the lower the mobility. Specifically, the mobility values of the microcrystalline silicon films that were deposited under the Conditions e and f, including an element aluminum concentration of more than 1.0×E16 (=1.0×10¹⁶) atoms/cm³, is smaller than 0.5 cm²/Vs, which is a typical mobility of an amorphous silicon film. Thus it can be seen that in order to obtain a microcrystalline silicon film with a mobility of more than 0.5 cm²/Vs, the concentration of the element aluminum should be reduced to 1.0×E16 atoms/cm³ or less. Also, as can be seen from FIG. 6, a TFT, including a microcrystalline silicon film with an element aluminum concentration of 1.0×E16 atoms/cm³ or less (which was fabricated under the Condition d), has a good Vg-Id characteristic, and an ON-state current, which is greater than that of an amorphous silicon TFT, can be obtained.

As described above, by using the high-density plasma CVD system 30, a microcrystalline silicon film, in which the concentration of element aluminum is 1.0×E16 atoms/cm³ or less, can be formed even without performing the process step of cleaning the inner wall of the chamber 26. Under each of the conditions described above, if the microwave has a power of 3.6 W/cm² or more, then the element aluminum has a concentration of more than 1.0×E16 atoms/cm³. That is why it is preferred that the power of the microwave be less than 3.6 W/cm². Also, the microwave preferably falls within the range of 500 MHz to 3 GHz and the pressure preferably falls within the range of 10 mT (=1.34 Pa) to 30 mT (=4.01 Pa).

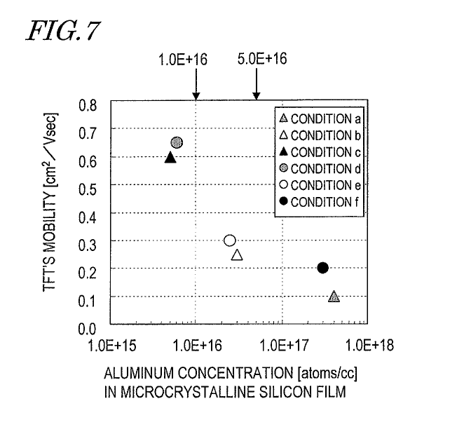

FIG. 7 is a graph summarizing how the mobility of a TFT changed with the concentration of element aluminum in the microcrystalline silicon film that had been formed under each of those conditions a through f. As can be seen easily from FIG. 7, in order to obtain a microcrystalline silicon film, of which the mobility is more than 0.5 cm²/Vs, the concentration of the element aluminum should be reduced to 1.0×E16 atoms/cm³ or less.

In the foregoing description of preferred embodiments, the TFT 10 is supposed to be a bottom-gate TFT. However, the present invention is in no way limited to those specific preferred embodiments but is naturally applicable to a top-gate TFT, too. Furthermore, the present invention is applicable to not just such a TFT including a microcrystalline silicon film as its active layer but also a TFT including a stack of a microcrystalline silicon film and an amorphous silicon film as its active layer as well. In order to use the high mobility of the microcrystalline silicon film effectively, the microcrystalline silicon film is preferably arranged closer to the gate electrode than the amorphous silicon film is so that a channel is formed in the microcrystalline silicon film.

The present invention is applicable for use in the TFT substrate of a semiconductor device including a microcrystalline silicon TFT such as a TFT liquid crystal display device or an organic EL display device and a method for fabricating such a device.

### REFERENCE SIGNS LIST

10 TFT
11, 11a substrate (glass substrate)
12 gate electrode
13 gate insulating film
14 active layer (microcrystalline silicon film)
15 contact layer
16 etch stop layer (channel protective layer)
17 drain electrode
18 source electrode
24 dielectric plate
25 metal layer
26 chamber

1. A method for fabricating a semiconductor device, the method comprising the steps of:
(a) providing a substrate in a chamber;
(b) supplying a microwave into the chamber through a dielectric plate, of which one surface that faces the chamber is made of alumina, thereby depositing a microcrystalline silicon film with an aluminum concentration of 1.0×10¹⁶ atoms/cm³ or less on the substrate by high-density plasma CVD process; and
(c) making a thin-film transistor that uses the microcrystalline silicon film as its active layer.

2. The method of claim 1, wherein the step (b) is performed with that surface of the dielectric plate that faces the chamber partially covered with a metal layer.

3. A semiconductor device fabricated by the method of claim 1.
